(19) United States
(12) Patent Application Publication
(10) Pub. No.: US 2011/0088774 A1
(43) Pub. Date: Apr. 21, 2011

(54) PHOTOVOLTAIC CELL AND PHOTOVOLTAIC CELL SUBSTRATE

(75) Inventors: Franck Gromball, Gelnhausen (DE); Emmanuelle Peter, Aix En Pce (FR); Stephane Auvray, Suresnes (FR); Eric Mattmann, Paris (FR); Ulrich Billert, La Celle Saint-Cloud (FR); Nikolas Janke, Herzogenrath (DE)

(73) Assignee: SAINT-GOBAIN GLASS FRANCE, COURBERVOIE (FR)

(21) Appl. No.: 12/918,149

(22) PCT Filed: Feb. 17, 2009
(86) PCT No.: PCT/FR09/50252

§ 371 Date: Dec. 10, 2010

(30) Foreign Application Priority Data
Feb. 18, 2008 (FR) 0851003

(51) Int. Cl. H01L 31/0216

(52) U.S. Cl. 136/256

(57) ABSTRACT

The invention relates to a photovoltaic cell (1) having an absorbent photovoltaic material, especially a cadmium-based material, said cell comprising a front face substrate (10), especially a transparent glass substrate, having, on a main surface, a transparent electrode coating (100) consisting of a thin-film stack that includes at least one metallic functional layer (40), especially one based on silver, and at least two antireflection coatings (20, 60), said antireflection coatings each comprising at least one antireflection layer (24, 26; 66, 68), said functional layer (40) being placed between the two antireflection coatings (20, 60), characterized in that the antireflection coating (60) placed above the metallic functional layer (40) on the opposite side from the substrate comprises at least two antireflection layers (66, 68), the antireflection layer (68) furthest from the metallic functional layer (40) being more resistive than the antireflection layer (66) closest to the metallic functional layer (40).

The invention relates to a photovoltaic cell front face substrate, especially a transparent glass substrate, and to a photovoltaic cell incorporating such a substrate.

In a photovoltaic cell, a photovoltaic system having a photovoltaic material which produces electrical energy through the effect of incident radiation is positioned between a backplate substrate and a front face substrate, this front face substrate being the first substrate through which the incident radiation passes before it reaches the photovoltaic material.

In the photovoltaic cell, the front face substrate usually has, beneath a main surface turned toward the photovoltaic material, a transparent electrode coating in electrical contact with the photovoltaic material placed beneath when the main direction of arrival of the incident radiation is considered to be via the top.

This front face electrode coating thus constitutes, in general, the negative terminal of the photovoltaic cell.

Of course, the photovoltaic cell also has in the direction of the backplate substrate an electrode coating that then constitutes the positive terminal of the photovoltaic cell, but in general the electrode coating of the backplate substrate is not transparent.

Within the context of the present invention, the term “photovoltaic cell” should be understood to mean any assembly of constituents that produces an electrical current between its electrodes by solar radiation conversion, whatever the dimensions of this assembly and whatever the voltage and the intensity of the current produced, and in particular whether or not this assembly of constituents has one or more internal electrical connections (in series and/or in parallel). The notion of a “photovoltaic cell” within the context of the present invention is therefore equivalent here to that of a “photovoltaic module” or a “photovoltaic panel”.

The material normally used for the transparent electrode coating of the front face substrate is in general a material based on a TCO (transparent conductive oxide), such as for example a material based on indium tin oxide (ITO) or based on aluminum-doped zinc oxide (ZnO:Al) or boron-doped zinc oxide (ZnO:B) or else based on fluorine-doped tin oxide (SnO₂:F).

These materials are deposited chemically, for example by CVD (chemical vapor deposition), optionally PECVD (plasma-enhanced CVD), or physically, for example by vacuum deposition by cathode sputtering, optionally magnetron sputtering (i.e. magnetically enhanced sputtering).

However, to obtain the desired electrical conduction, or rather the desired low resistance, the electrode coating made of a TCO-based material must be deposited with a relatively large physical thickness, of around 500 to 1000 nm and even sometimes higher, this being costly as regards the cost of these materials when they are deposited as layers with this thickness.

When the deposition process requires a heat supply, this further increases the manufacturing cost.

Another major drawback of electrode coatings made of a TCO-based material lies in the fact that, for a chosen material, its physical thickness is always a compromise between the electrical conduction finally obtained and the transparency finally obtained, since the greater the physical thickness, the higher the conductivity but the lower the transparency, while conversely, the lower the physical thickness, the higher the transparency but the lower the conductivity.

It is therefore not possible with electrode coatings made of a TCO-based material to independently optimize the conductivity of the electrode coating and its transparency.

The prior art of international patent application WO 01/43204 teaches a process for manufacturing a photovoltaic cell in which the transparent electrode coating is not made of a TCO-based material but consists of a thin-film stack deposited on a main face of the front face substrate, this coating comprising at least one metallic functional layer, especially one base on silver, and at least two antireflection coatings, said antireflection coatings each comprising at least one antireflection layer, said functional layer being placed between the two antireflection coatings.

This process is noteworthy in that it provides for at least one highly refringent layer made of an oxide or nitride to be deposited beneath the metallic functional layer and above the photovoltaic material when considering the direction of the incident light entering the cell from above.

That document provides an exemplary embodiment in which the two antireflection coatings which flank the metallic functional layer, namely the antireflection coating placed beneath the metallic functional layer in the direction of the substrate and the antireflection coating placed above the metallic functional layer on the opposite side from the substrate, each comprise at least one layer made of a highly refringent material, in this case zinc oxide (ZnO) or silicon nitride (Si₃N₄).

However, this solution can be further improved.

The prior art also discloses U.S. Pat. No. 6,169,246 relating to a photovoltaic cell having a cadmium-based absorbent photovoltaic material, said cell comprising a transparent glass front face substrate having, on a main surface, a transparent electrode coating consisting of a TCO (transparent conductive oxide).

According to that document, a buffer layer made of zinc stannate is interposed above the TCO electrode coating and beneath the photovoltaic material, said buffer layer therefore forming neither part of the TCO electrode coating nor of the photovoltaic material.

An important object of the invention is to allow charge transport between the electrode coating and the photovoltaic material, especially a cadmium-based material, to be easily controlled and the efficiency of the cell to be consequently improved.

Another important object is also to produce a transparent thin-film-based electrode coating that is simple to produce and as inexpensive as possible to manufacture on an industrial scale.

Thus, one subject of the invention, in its broadest acceptance, is a photovoltaic cell having an absorbent photovoltaic material, especially a cadmium-based material, as claimed in claim 1. This cell comprises a front face substrate, especially a transparent glass substrate, having, on a main surface, a transparent electrode coating consisting of a thin-film stack that includes at least one metallic functional layer, especially one based on silver, and at least two antireflection coatings, said antireflection coatings each comprising at least one antireflection layer, said functional layer being placed between the two antireflection coatings, characterized in that the antireflection coating placed above the metallic functional layer on the opposite side from the substrate comprises at least two antireflection layers, the antireflection layer furthest from the metallic functional layer being more resistive than the antireflection layer closest to the metallic functional layer.

The resistivity ρ corresponds to the product of the resistance per square R of the layer multiplied by its actual thickness.

In a preferred variant of the invention, the antireflection layer furthest from the metallic functional layer has a resistivity equal to at least 5 times, or even at least 10 times, or even at least 50 times, or even at least 100 times, or even at least 200 times, or at least 500 times, or even at least 1000 times the resistivity of the antireflection layer closest to the metallic functional layer.

The antireflection layer furthest from the metallic functional layer, the one which is more resistive, preferably has a resistivity ρ of between 5×10⁻³ Ω.cm and 10 Ω.cm, or between 10⁻² Ω.cm and 5 Ω.cm or even between 5×10⁻² Ω.cm and 1 Ω.cm.

The antireflection layer closest to the metallic functional layer, the one which is more conductive, preferably has a resistivity ρ of between 10⁻⁵ Ω.cm and 5×10⁻³ Ω.cm, excluding the latter value, or between 5×10⁻⁴ Ω.cm and 2×10⁻³ Ω.cm or even between 10⁻⁴ Ω.cm and 10⁻³ Ω.cm.

Moreover, the antireflection layer furthest from the metallic functional layer has an optical thickness preferably representing between 2 and 50% of the total optical thickness of the antireflection coating furthest from the substrate and especially an optical thickness representing between 2 and 25% or even between 5 and 20% of the total optical thickness of the antireflection coating furthest from the substrate.

This antireflection layer furthest from the metallic functional layer preferably has an actual thickness of between 2 and 100 nm and preferably between 5 and 50 nm or even between 10 and 30 nm.

An antireflection layer is preferably based on:
optionally doped zinc oxide ZnO, such as for example ZnO:Al, ZnO:B, or ZnO:Ga;
optionally doped tin oxide SnO₂, such as for example, SnO₂:F;
optionally doped titanium oxide TiO₂, such as for example TiO₂:Nb;
optionally doped gallium oxide Ga₂O₃;
optionally doped indium oxide In₂O₃;
optionally doped silicon oxide SiO₂;
or based on a mixed indium tin oxide ITO,
a mixed gallium zinc oxide GZO,
a mixed indium zinc oxide IZO,
a mixed zinc tin oxide Zn₂SnO₄, or
a mixed indium gallium zinc oxide IGZO, this oxide being optionally nonstoichiometric.

The antireflection layer closest to the metallic functional layer is preferably in general based on a transparent conductive oxide (TCO) obtained from at least one of the elements in the following list: Al, Ga, Sn, Zn, Sb, In, Cd, Ti, Zr, Ta, W and Mo, and especially an oxide based on one of these elements doped with at least one other of these elements, this oxide being optionally substoichiometric in oxygen.

The term “doping” is understood here to mean the presence of at least one other metallic element in the layer, in an atomic proportion of metal (or oxygen element) ranging from 0.5 to 10%.

A mixed oxide here is an oxide of metallic elements, each metallic element of which is present in an atomic proportion of metal (excluding oxygen element) of at most 10%.

In one particular embodiment, the antireflection layer closest to the metallic functional layer and the antireflection layer furthest from the metallic functional layer are based on the same oxide, especially based on:
zinc oxide ZnO;
tin oxide SnO₂;
titanium oxide TiO₂;
gallium oxide Ga₂O₃;
indium oxide In₂O₃;
silicon oxide SiO₂; or
based on a mixed indium tin oxide ITO,
a mixed gallium zinc oxide GZO,
a mixed indium zinc oxide IZO,
a mixed zinc tin oxide Zn₂SnO₄, or
a mixed indium gallium zinc oxide IGZO, this oxide being optionally nonstoichiometric.

The antireflection layer closest to the metallic functional layer, the one which is less resistive, preferably constitutes the first layer of the upper antireflection coating that is placed above the metallic functional layer, on the opposite side from the substrate.

The antireflection layer furthest from the metallic functional layer, the one which is more resistive, preferably constitutes the final layer of the upper antireflection coating that is placed above the metallic functional layer on the opposite side from the substrate. This antireflection layer furthest from the metallic functional layer thus preferably constitutes the final layer of the electrode coating and is thus directly in contact with the photovoltaic material.

The interface between, on the one hand, the electrode coating according to the invention which incorporates, in particular, in its optical definition, the more resistive final layer, and, on the other hand, the photovoltaic material, in particular a cadmium-based material, is preferably as smooth as possible.

The antireflection layer furthest from the metallic functional layer thus preferably has a surface roughness of between 5 and 250 ångströms, especially 15 and 100 ångströms or between 10 and 50 ångströms.

Observing that the absorption of the usual photovoltaic materials differs from one material to the other, the inventors have sought to define the essential optical characteristics needed for the definition of a thin-film stack of the type presented above for forming a front face electrode coating for a solar cell.

The antireflection coating placed above the metallic functional layer on the opposite side from the substrate preferably has an optical thickness equal to about one half of the maximum absorption wavelength λₘ of the photovoltaic material.

The antireflection coating placed beneath the metallic functional layer in the direction of the substrate preferably has an optical thickness of about one eighth of the maximum absorption wavelength λₘ of the photovoltaic material.

In a preferred variant, the maximum absorption wavelength λₘ of the photovoltaic material is however weighted by the solar spectrum. In this embodiment, the antireflection coating placed above the metallic functional layer on the opposite side of the substrate has an optical thickness equal to about one half of the maximum wavelength λ_{M} of the product of the absorption spectrum of the photovoltaic material multiplied by the solar spectrum.

In this variant, too, the antireflection coating placed beneath the metallic functional layer in the direction of the substrate has an optical thickness equal to about one eighth of the maximum wavelength λ_{M} of the product of the absorption spectrum of the photovoltaic material multiplied by the solar spectrum.

In a preferred version, the antireflection coating placed above the metallic functional layer has an optical thickness of between 0.45 and 0.55 times the maximum absorption wavelength λₘ of the photovoltaic material, these values being inclusive, and preferably said antireflection coating placed above the metallic functional layer has an optical thickness of between 0.45 and 0.55 times the maximum wavelength λ_{M} of the product of the absorption spectrum of the photovoltaic material multiplied by the solar spectrum, these values being inclusive.

Also in a preferred version, the antireflection coating placed beneath the metallic functional layer has an optical thickness of between 0.075 and 0.175 times the maximum absorption wavelength λₘ of the photovoltaic material, these values being inclusive, and preferably said antireflection coating placed beneath the metallic functional layer has an optical thickness of between 0.075 and 0.175 times the maximum wavelength λ_{M} of the product of the absorption spectrum of the photovoltaic material multiplied by the solar spectrum, these values being inclusive.

Thus, according to the invention, an optimum optical path is defined as a function of the maximum absorption wavelength λₘ of the photovoltaic material or preferably as a function of the maximum wavelength λ_{M} of the product of the absorption spectrum of the photovoltaic material multiplied by the solar spectrum, so as to obtain the highest efficiency of the photovoltaic cell.

The solar spectrum to which reference is made here is the AM 1.5 solar spectrum as defined by the ASTM standard.

Within the context of the present invention, the term “coating” should be understood to mean that there may be several layers of different materials within the coating.

Within the context of the present invention, the term “antireflection layer” should be understood to mean that, from the standpoint of its nature, the material is “nonmetallic” i.e. it is not a metal. Within the context of the invention, this term should be understood not to introduce any limitation on the resistivity of the material, which may be that of a conductor (in general, ρ<10⁻³ Ω.cm), that of an insulator (in general, ρ>10⁹ Ω.cm) or that of a semiconductor (in general between the above two values).

Completely surprisingly and independently of any other characteristic, the optical path of an electrode coating having a thin-film stack with a functional monolayer, which has an antireflection coating placed above the metallic functional layer having an optical thickness equal to about four times the optical thickness of the antireflection coating placed beneath the metallic functional layer, makes it possible to improve the efficiency of the solar cell, and also to improve its resistance to the stresses generated during operation of the cell.

The purpose of the coatings that flank the metallic functional layer is to “antireflect” this metallic functional layer. This is why they are called “antireflection coatings”.

Indeed, although the functional layer enables by itself the desired conductivity of the electrode coating to be obtained, even with a small physical thickness (of the order of 10 nm), said layer will strongly oppose the passage of light, and of electromagnetic radiation.

In the absence of such an antireflection system, the light transmission would then be much too low and the light reflection much too high (in the visible and in the near infrared, since it is a question of producing a photovoltaic cell).

The term “optical path” has here a specific meaning and is used to denote the tally of the various optical thicknesses of the various antireflection coatings subjacent and superjacent to the (or each) metallic functional layer of the interference filter thus produced. It will be recalled that the optical thickness of a coating is equal to the product of the physical thickness of the layer multiplied by the index of its material when there is only a single layer in the coating, or the sum of the products of the physical thickness of each layer multiplied by the index of the material of each layer when there are several layers.

The optical path according to the invention is, in the absolute, a function of the physical thickness of the metallic functional layer, but in fact, within the range of physical thicknesses of the metallic functional layer enabling the desired conductance to be obtained, it turns out that it does not so to speak vary. Thus, the solution according to the invention is suitable when the functional layer(s) is (or are) based on silver, and has (or have in total) a physical thickness of between 5 and 20 nm, these values being inclusive.

The type of thin-film stack according to the invention is known in the field of architectural or automotive glazing, in order to produce glazing of enhanced thermal insulation of the “low-E (low-emissivity)” and/or “solar control” type.

The inventors thus noticed that certain stacks of the type of those used for low-E glazing in particular could be used to produce electrode coatings for a photovoltaic cell, and in particular the stacks known as “temperable” stacks or stacks “to be tempered”, i.e. those used when it is desired to subject the substrate carrying the stack to a tempering treatment, in particular to a tempering heat treatment.

Thus, another subject of the present invention is the use of a thin-film stack for architectural glazing and especially a stack of this type having the features of the invention that is “temperable” or is “to be tempered”, especially a low-E stack according to the invention, particularly one that is “temperable” or “to be tempered”, in order to produce a photovoltaic cell front face substrate.

The term “temperable” stack or substrate within the context of the present invention should be understood to mean that the essential optical properties and thermal properties (expressed by the resistance per square, which is directly related to the emissivity) are preserved during the heat treatment.

Thus, it is possible on one and the same building façade for example to place close together glazing panels incorporating tempered substrates and untempered substrates, both coated with the same stack, without it being possible to distinguish one from another by simple visual observation of the color in reflection and/or of the light reflection/transmission.

For example, a stack or substrate coated with a stack having the following changes, before and after heat treatment, will be considered to be temperable since these changes will not be perceptible to the eye:
a small change in light transmission ΔT_{L} (in the visible) of less than 3%, or even less than 2%; and/or
a small change in light reflection ΔR_{L} (in the visible) of less than 3%, or even less than 2%; and/or
a small change in color (in the Lab system) ΔE={square root over (((ΔL*)²+(Δa*)²+(Δb*)²))} of less than 3 or even less than 2.

A stack or substrate “to be tempered” within the context of the present invention should be understood to mean that the optical and thermal properties of the coated substrate are acceptable after heat treatment, whereas they were not, or in any case were not all, previously.

For example, a stack, or a substrate coated with a stack, having after the heat treatment the following characteristics will be considered “to be tempered” within the context of the present invention, whereas prior to the heat treatment at least one of these characteristics was not fulfilled:
a high light transmission T_{L} (in the visible) of at least 65%, or even 70% or even at least 75%; and/or
a low light absorption (in the visible, defined by 1-T_{L}-R_{L}) of less than equal to or 10%, or even less than equal to or 8% or even less than equal to or 5%; and/or
a resistance per square R_{□} at least as good as that of the conductive oxides normally used, and in particular less than equal to or 20Ω/□, or even less than equal to or 15Ω/□ or even equal to or less than 10Ω/□.

Thus, the electrode coating must be transparent. It must therefore have, when deposited on the substrate, in the wavelength range between 300 and 1200 nm, a minimum average light transmission of 65%, or even 75% and more preferably 85% and even more especially at least 90%.

If the front face substrate has undergone a heat treatment, especially a toughening heat treatment, after deposition of the thin layers and before it is fitted into the photovoltaic cell, it is quite possible, before this heat treatment, for the substrate coated with the stack acting as electrode coating to be of low transparency. For example, it may have, before this heat treatment, a light transmission in the visible of less than 65% or even less than 50%.

The important point is that the electrode coating should be transparent before heat treatment and be such that it has, after the heat treatment, in the wavelength range between 300 and 1200 nm, an average light transmission (in the visible) of at least 65%, or even 75% and more preferably 85% and even more especially at least 90%.

Moreover, within the context of the invention, the stack does not have, in the absolute, the best possible light transmission but does have the best possible light transmission within the context of the photovoltaic cell according to the invention.

The antireflection coating placed beneath the metallic functional layer may also have a chemical barrier function, acting as a barrier to diffusion, and in particular to the diffusion of the sodium coming from the substrate, therefore protecting the electrode coating, and more particularly the metallic functional layer, especially during any heat treatment, especially toughening heat treatment.

In another particular embodiment, the substrate includes, beneath the electrode coating, a base antireflection layer having a low refractive index close to that of the substrate, said base antireflection layer preferably being based on silicon oxide or based on aluminum oxide or based on a mixture of the two.

Furthermore, this dielectric layer may constitute a chemical diffusion barrier layer, and in particular a barrier to the diffusion of the sodium coming from the substrate, therefore protecting the electrode coating, and more particularly the metallic functional layer, especially during any heat treatment, especially a toughening heat treatment, or for the processing of the photovoltaic material.

Within the context of the invention, a dielectric layer is a layer which does not participate in the electric charge displacement (electrical current) or one in which the effect of participation in the electric charge displacement may be considered to be zero compared with that of the other layers of the electrode coating.

Moreover, this base antireflection layer preferably has a physical thickness of between 10 and 300 nm or between 35 and 200 nm and even more preferably between 50 and 120 nm.

This metallic functional layer may be based on silver, copper or gold, and may optionally be doped with at least one other of these elements.

The expression “based on” is understood in the usual manner to mean a layer containing predominantly the material, i.e. containing at least 50% of this material by molar mass. The expression “based on” therefore covers doping.

The metallic functional layer is preferably deposited in a crystallized form on a thin dielectric layer which is also preferably crystallized (therefore called a “wetting layer” as it promotes the suitable crystalline orientation of the metallic layer deposited on top).

The thin-film stack producing the electrode coating is preferably a functional monolayer coating, i.e. a single functional layer. However, it may be a functional multilayer, and especially a functional bilayer.

The functional layer is thus preferably deposited above, or even directly on, a wetting layer based on an oxide, especially based on zinc oxide and optionally doped, optionally with aluminum.

The physical (or actual) thickness of the wetting layer is preferably between 2 and 30 nm and more preferably between 3 and 20 nm.

This wetting layer is a dielectric and is a material preferably having a resistivity ρ (defined by the product of the resistance per square of the layer multiplied by its thickness) such that 0.5 Ω.cm<ρ<200 Ω.cm or such that 50Ω.cm<ρ<200 Ω.cm.

The stack is generally obtained by a succession of depositions performed using a vacuum technique such as sputtering, optionally magnetron sputtering. It is also possible to provide one or even two very thin coatings called “blocker coatings” that do not form part of the antireflection coatings, which is (are) placed directly under, onto or on each side of each functional, especially silver-based, metallic layer, the coating subjacent to the functional layer, in the direction of the substrate, as tie, nucleating and/or protective coating during the possible heat treatment carried out after the deposition, and the coating superjacent to the functional layer as protective or “sacrificial” coating so as to prevent the metallic functional layer from being impaired by attack and/or migration of oxygen from a layer above it, especially during any heat treatment, or even also by migration of oxygen if the layer above it is deposited by sputtering in the presence of oxygen.

Within the context of the present invention, when it is specified that a layer or coating (comprising one or more layers) is deposited directly beneath or directly on another deposited layer or coating, there can be no interposition of another layer between these two deposited layers or coatings.

Preferably, at least one blocker coating is based on Ni or on Ti or is based on an Ni-based alloy, especially based on an NiCr alloy.

Preferably, the coating beneath the metallic functional layer in the direction of the substrate comprises a layer based on a mixed oxide, in particular based on a zinc tin mixed oxide or an indium tin mixed oxide (ITO).

Moreover, the coating beneath the metallic functional layer in the direction of the substrate and/or the coating above the metallic functional layer may comprise a layer having a high refractive index, especially one equal to or greater than 2, such as for example a layer based on silicon nitride, optionally doped, for example with aluminum or zirconium.

Moreover, the coating beneath the metallic functional layer in the direction of the substrate and/or the coating above the metallic functional layer may comprise a layer having a very high refractive index, especially one equal to or greater than 2.35, such as for example a layer based on titanium oxide.

The substrate may include a coating based on a photovoltaic material, especially a cadmium-based material, above the electrode coating on the opposite side from the front face substrate.

A preferred structure of a front face substrate according to the invention is thus of the type: substrate/(optional antireflection base layer)/electrode coating/photovoltaic material, or else of the type: substrate/(optional antireflection base layer)/electrode coating/photovoltaic material/electrode coating.

In one particular variant, the electrode coating consists of a stack for architectural glazing, especially a “temperable” stack for architectural glazing or a stack for architectural glazing “to be tempered”, and in particular a low-E stack, especially a “temperable” low-E stack or a low-E stack “to be tempered”, this thin-film stack having the features of the invention.

The present invention also relates to a substrate for a photovoltaic cell according to the invention, especially a substrate for architectural glazing coated with a thin-film stack having the features of the invention, especially a “temperable” substrate for architectural glazing or a substrate for architectural glazing “to be tempered” having the features of the invention, and in particular a low-E substrate, especially a “temperable” low-E substrate or a low-E substrate “to be tempered” having the features of the invention.

All the layers of the electrode coating are preferably deposited by a vacuum deposition technique, but it is not however excluded for the first layer or first layers of the stack to be able to be deposited by another technique, for example by a thermal decomposition technique of the pyrolysis type or by CVD, optionally under vacuum, and optionally plasma-enhanced.

Advantageously, the electrode coating according to the invention having a thin-film stack is moreover much more resistant than a TCO electrode coating. Thus, the lifetime of the photovoltaic cell may be increased.

Also advantageously, because of its small physical thickness, compared with that of an electrode made of a TCO-based material, an electrode consisting of one or more metallic functional layers according to the invention is much easier to etch, in particular by laser etching: lower energy and shorter time, it being unnecessary to carry out the longitudinal separation step (called “modularization” step) generally over the entire thickness of the electrode; furthermore, this etching step results in less material being removed, for an identical etching width, than for an electrode made of a TCO-based material and consequently reduces the risk of contaminating the cell with the material removed.

Also advantageously, the electrode coating according to the invention can just as well be used as rear face electrode coating, in particular when it is desired for at least a small portion of the incident radiation to pass completely through the photovoltaic cell.

The details and advantageous features of the invention will emerge from the following nonlimiting examples, illustrated by the figures appended herewith, in which:

FIG. 1 illustrates a photovoltaic cell front face substrate of the prior art coated with an electrode coating made of a transparent conductive oxide and having a base antireflection layer;

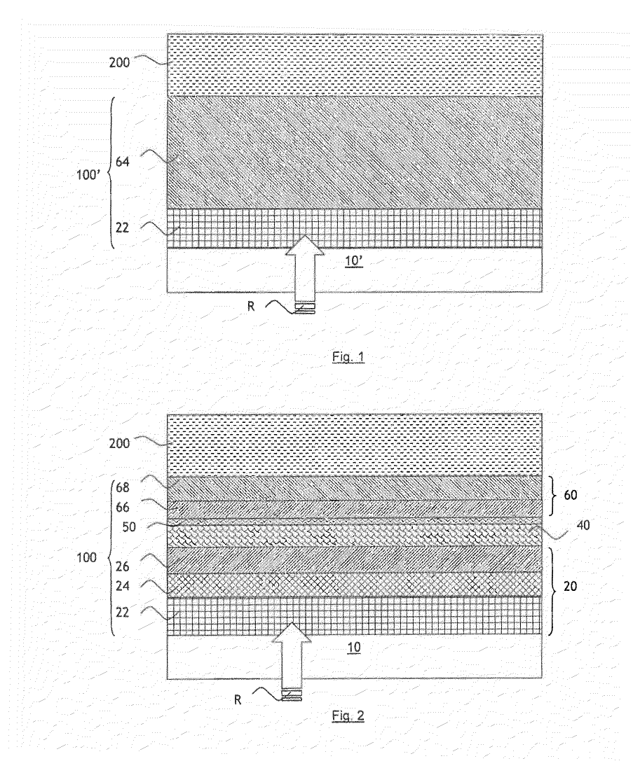

FIG. 2 illustrates a photovoltaic cell front face substrate according to the invention coated with an electrode coating consisting of a functional monolayer thin-film stack and having a base antireflection layer;

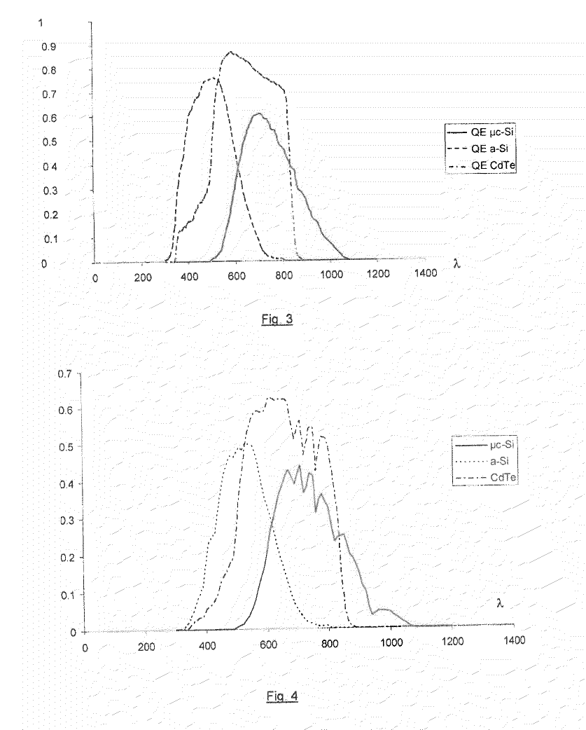

FIG. 3 illustrates the quantum efficiency curve for three photovoltaic materials;

FIG. 4 illustrates the actual yield curve corresponding to the product of the absorption spectrum of these three photovoltaic materials multiplied by the solar spectrum;

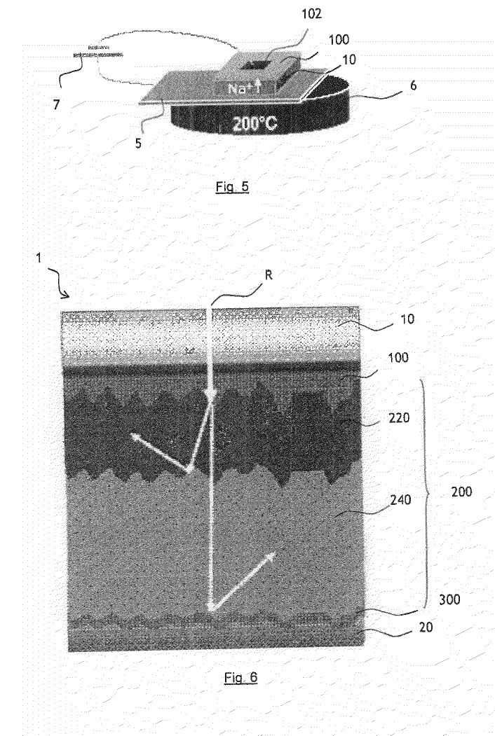

FIG. 5 illustrates the principle of the durability test for the photovoltaic cells; and

FIG. 6 illustrates a cross-sectional diagram of a photovoltaic cell.

In FIGS. 1, 2, 5 and 6, the proportions of the thicknesses of the various coatings, layers and materials have not been strictly respected so as to make them easier to examine.

FIG. 1 illustrates a photovoltaic cell front face substrate 10′ of the prior art having an absorbent photovoltaic material 200, said substrate 10′ having, on a main surface, a transparent electrode coating 100′ consisting of a TCO layer 66 that conducts the current.

The front face substrate 10′ is placed in the photovoltaic cell in such a way that the front face substrate 10′ is the first substrate through which the incident radiation R passes before reaching the photovoltaic material 200.

The substrate 10′ also includes, beneath the electrode coating 100′, i.e. directly on the substrate 10′, a base antireflection layer 22 having a low refractive index n₂₂ close to that of the substrate.

The substrate 10′ may furthermore comprise, on the electrode coating 100′ and beneath the photovoltaic material 200, a buffer layer (not illustrated).

FIG. 2 illustrates a photovoltaic cell front face substrate 10 according to the invention.

The front face substrate 10 also has on a main surface a transparent electrode coating 100, but here this electrode coating 100 consists of a thin-film stack comprising at least one metallic functional layer 40, based on silver, and at least two antireflection coatings 20, 60, said coatings each comprising at least one thin antireflection layer 24, 26; 66, 68, said functional layer 40 being placed between the two antireflection coatings, one called the subjacent antireflection coating 20 located beneath the functional layer, in the direction of the substrate, and the other called the superjacent antireflection coating 60 located above the functional layer, in the opposite direction to the substrate.

The thin-film stack constituting the transparent electrode coating 100 of FIG. 2 has a stack structure of the type of that of a low-E substrate, optionally temperable or to be tempered, with a functional monolayer, such as may be found commercially for applications in the field of architectural glazing for buildings.

Two examples, numbered 1 and 2, were produced on the basis of the stack structure with a functional monolayer illustrated:
in the case of example 1 on the basis of FIG. 1; and
in the case of example 2 on the basis of FIG. 2, except that the stack does not include an overblocker coating.

Moreover, in all the examples below, the layers are deposited on a substrate 10′, 10 made of clear soda-lime glass 4 mm in thickness.

The indices given below were measured at the usual 550 nm wavelength.

The electrode coating 100′ of example 1 is based on conductive aluminum-doped zinc oxide.

The stack constituting an electrode coating 100 of example 2 consists of a thin-film stack comprising, in order:
an antireflection layer 24, which is a dielectric layer based on titanium oxide, with an index n=2.4;
an antireflection layer 26, which is a dielectric oxide-based wetting layer, especially one based on optionally doped zinc oxide, with an index n=2;
optionally, a subjacent blocker coating (not illustrated), for example based on Ti or based on an NiCr alloy that could be placed directly beneath the functional layer 40, but is not provided here; this coating is in general necessary if there is no wetting layer 26, but is not necessarily essential;
the single functional layer 40, made of silver, is thus placed here directly on the wetting coating 26;
a superjacent blocker coating 50 based on Ti or based on an NiCr alloy could be placed directly on the functional layer 40, but is not provided in the examples produced;
a conductive antireflection layer 66, based on aluminum-doped zinc oxide, having an index n=2, its resistivity being between 0.35×10⁻³ Ω.cm and 2.5×10⁻³ Ω.cm, in particular approximately 10⁻³ Ω.cm, this layer being deposited here from a ceramic target (composed of about 2% aluminum, 49% zinc and 49% oxygen) in an argon atmosphere directly on the functional layer 40; and then
a dielectric termination layer 68, which is antireflecting and is based on tin zinc oxide SnₓZn_{y}O_{z}, with an index n=2.1, having a resistivity of the order of 1 Ω.cm, this layer being deposited here from a metal target (composed of about 50% tin and 50% zinc) in an atmosphere composed of 25% oxygen (O₂) and 75% argon.

It should be noted that the layers based on mixed tin zinc oxide over their entire thickness may have over their entire thickness variable Sn/Zn ratios or variable dopant concentrations, depending on the targets used to deposit these layers and in particular when several targets of different compositions are used to deposit a layer.

In the examples, the photovoltaic material 200 is based on cadmium telluride.

The quantum efficiency QE of this material is illustrated in FIG. 3 together with that of microcrystallized silicon (the crystallite size of which is of the order of 100 nm) and of amorphous (i.e. uncrystallized) silicon—other photovoltaic materials that are also suitable within the context of the invention.

It will be recalled here that the quantum efficiency QE is, as is known, the expression for the probability (between 0 and 1) of an incident photon with a wavelength given on the x-axis being transformed into an electron-hole pair.

As may be seen in FIG. 3, the maximum absorption wavelength λₘ, i.e. the wavelength at which the quantum efficiency is a maximum (i.e. at its highest value):
of amorphous silicon a-Si, i.e. λₘ(a-Si), is 520 nm;
of microcrystallized silicon μc-Si, i.e. λₘ(μc-Si), is 720 nm; and
of cadmium telluride CdTe, i.e. λₘ(CdTe), is 600 nm.

In a first approximation of the optical path of the stack, this maximum absorption wavelength λₘ is sufficient.

The antireflection coating 20 placed beneath the metallic functional layer 40 in the direction of the substrate therefore has an optical thickness equal to about one eighth of the maximum absorption wavelength λₘ of the photovoltaic material and the antireflection coating 60 placed above the metallic functional layer 40 on the opposite side from the substrate then has an optical thickness equal to about one half of the maximum absorption wavelength λₘ of the photovoltaic material.

Table 1 below summarizes the preferred ranges of the optical thicknesses in nm for each coating 20, 60 and for these three materials.

TABLE 1

| Material | | a-Si | μc-Si | CdTe |
|---|---|---|---|---|
| Coating | λₘ/2 | 260 | 360 | 300 |
| 60 | 0.45λₘ | 234 | 324 | 270 |
| | 0.55λₘ | 286 | 396 | 330 |
| Coating | λₘ/8 | 65 | 90 | 75 |
| 20 | 0.075λₘ | 39 | 54 | 45 |
| | 0.175λₘ | 91 | 126 | 105 |

However, it has been found that the optical definition of the stack may be improved by considering the quantum efficiency in order to obtain an improved actual yield by convolving this probability with the wavelength distribution of the solar light at the surface of the Earth. Here, we use the normalized solar spectrum AM1.5.

In this case, the antireflection coating 20 placed beneath the metallic functional layer 40 in the direction of the substrate has an optical thickness equal to about one eighth of the maximum wavelength λ_{M} of the product of the absorption spectrum of the photovoltaic material multiplied by the solar spectrum and the antireflection coating 60 placed above the metallic functional layer 40 on the opposite side from the substrate has an optical thickness equal to about one half of the maximum wavelength λ_{M} of the product of the absorption spectrum of the photovoltaic material multiplied by the solar spectrum.

As may be seen in FIG. 4, the maximum wavelength λ_{M} of the product of the absorption spectrum of the photovoltaic material multiplied by the solar spectrum, i.e. the wavelength at which the yield is a maximum (i.e. at its highest value):
of amorphous silicon a-Si, i.e. λ_{M}(a-Si), is 530 nm;
of microcrystalline silicon μc-Si, i.e. λ_{M}(μc-Si), is 670 nm; and
of cadmium telluride CdTe, i.e. λ_{M}(CdTe), is 610 nm.

Table 2 below summarizes the preferred ranges of the optical thicknesses in nm for each coating 20, 60 and for each of these three materials.

TABLE 2

| Material | | a-Si | μc-Si | CdTe |
|---|---|---|---|---|
| Coating | λ_{M}/2 | 265 | 335 | 305 |
| 60 | 0.45λ_{M} | 239 | 302 | 275 |
| | 0.55λ_{M} | 292 | 369 | 336 |
| Coating | λ_{M} /8 | 66 | 84 | 76 |
| 20 | 0.075λ_{M} | 40 | 50 | 46 |
| | 0.175λ_{M} | 93 | 117 | 107 |

In all the examples, a base antireflection layer 22 based on silicon oxide was deposited directly on the substrate. Since its refractive index n₁₅ is low and close to that of the substrate, its optical thickness has not been taken into account in the definition of the optical path of the stack according to the invention.

The conditions under which these layers are deposited are known to those skilled in the art since they are stacked in a similar manner to those used for low-emissivity or solar-control applications.

In this regard, a person skilled in the art may refer to patent applications EP 718 250, EP 847 965, EP 1 366 001, EP 1 412 300 or EP 722 913.

Table 3 below summarizes the materials and the physical thicknesses measured in nanometers of each of the layers of each of the examples 1 and 2 and Table 4 presents the main characteristics of these examples.

The performance characteristic P is calculated by what is called the “TSQE” method, in which the product of the integration of the spectrum over the entire radiation range in question with the quantum efficiency QE of the cell is used.

The light reflection characteristic R_{L} is measured under illuminant D₆₅.

Both examples 1 and 2 were subjected to a test for measuring the resistance of the electrode coatings to the stresses generated during operation of the cell (especially the presence of an electrostatic field), made in accordance with that illustrated in FIG. 5.

For this test, a portion of the substrate 10, 10′, for example measuring 5 cm×5 cm and coated respectively with the electrode coating 100, 100′, but without the photovoltaic material 200, is deposited on a metal plate 5 placed on a heat source 6 at about 200° C.

The test involves applying an electric field to the substrate 10, 10′ coated with the electrode coating 100, 100′ for 20 minutes, an electrical contact 102 being produced on the surface of said coating, and this contact 102 and the metal plate 5 being connected to the terminals of a power supply 7 delivering a DC current at about 200 V.

At the end of the test, once the specimen has cooled, the percentage of coating remaining is measured over the entire surface of the specimen.

This percentage of coating remaining after the resistance test is denoted by % CR.

Furthermore, independently of the preceding test, example 2 was subjected to a heat treatment (HT) consisting of annealing at a temperature of about 620° C. for 6 minutes followed by sudden cooling in ambient air (20° C.), simulating a toughening operation. The data measured after this heat treatment are given in the last column of Table 4. The heat treatment applied is thus more stressing than the usual heat treatment undergone by the electrode coating within the context of the process for depositing the cadmium-based photovoltaic coating.

TABLE 3

| Layers/material | Ex. 1 | Ex. 2 |
|---|---|---|
| 200: CdTe | 5000 | 5000 |
| 68: SnₓZn_{y}O_{z} | | 10 |
| 66: ZnO: Al | | 135 |
| 64: ZnO: Al | 1020 | |
| 40: Ag | | 7 |
| 26: ZnO | | 7 |
| 24: TiO₂ | | 27 |
| 22: SiO₂ | 110 | 110 |

TABLE 4

Ex. 2

| | Ex. 1 | Before HT | After HT |
|---|---|---|---|
| R (ohms/□) | 11.3 | 7.4 | 7.4 |
| P (%) | 83.9 | 84.1 | 84.8 |
| R_{L} (%) | 10.1 | 8 | 7.1 |

In example 2, the optical thickness of the coating 60 above the metallic functional layer is 291 nm (=135×2+10×2.1), and the optical thickness of the coating 20 beneath the metallic functional layer is 78.8 nm (=27×2.4+7×2).

This example shows that it is possible to obtain an electrode coating consisting of a thin-film stack and coated with cadmium telluride that has a better resistance per square R (−2.6 ohms/□) and a better performance P (+0.2%) than a TCO electrode coating coated with the same material (example 1). The optical thicknesses of the coatings 20 and 60 of example 2 fall within the ranges recommended for a CdTe photovoltaic material 200 according to Table 1 and Table 2.

The use of a cadmium-based photovoltaic material and in particular one combining CdTe with CdS, requires the electrode coating to withstand a heat treatment since the processing of this photovoltaic material requires a step at a temperature between 300° C. and 700° C., generally carried out in a controlled non-oxidizing atmosphere.

Surprisingly, it turns out that this step is quite similar to a toughening step as known to those skilled in the art of glass substrates for vehicles or buildings, even if generally the toughening atmosphere is not controlled.

Thus, it is particularly advantageous, when the photovoltaic material is based on cadmium, to choose a thin-film stack known for vehicular or building applications which is resistant to the toughening heat treatment, called a “temperable” stack or a stack “to be tempered”.

Thus, example 2 shows that the variations in the data during the applied heat treatment are slight. The stack chosen may therefore be considered to be “temperable”.

Furthermore, it is worthwhile pointing out that the thin-film stacks forming the electrode coating within the context of the invention have, both before and after heat treatment, a light reflection without the photovoltaic material which is lower than that of the TCO electrode coating without the photovoltaic material.

FIG. 6 illustrates a photovoltaic cell 1 provided with a front face substrate 10 according to the invention, seen in cross section, through which incident radiation R penetrates, and with a backplate substrate 20.

The photovoltaic material 200, for example made of amorphous silicon or crystalline or microcrystalline silicon or else cadmium telluride or copper indium diselenide (CuInSe₂, or CIS) or copper indium gallium selenium, is located between these two substrates. It consists of a layer of n-doped semiconductor material 220 and a layer of p-doped semiconductor material 240 that will produce the electrical current. The electrode coatings 100, 300, inserted respectively between, on the one hand, the front face substrate 10 and the layer of n-doped semiconductor material 220 and, on the other hand, between the layer of p-doped semiconductor material 240 and the backplate substrate 20, complete the electrical structure.

The electrode coating 300 may be based on silver or aluminum, or it may also consist of a thin-film stack having at least one metallic functional layer and in accordance with the present invention.

The present invention has been described in the foregoing by way of example. Of course, a person skilled in the art is capable of producing various alternative forms of the invention without thereby departing from the scope of the patent as defined by the claims.

1. A photovoltaic cell comprising an absorbent photovoltaic material, said photovoltaic cell comprising a front face substrate comprising, on a main surface, a transparent electrode coating comprising a thin-film stack that includes at least one metallic functional layer, and at least two antireflection coatings, said antireflection coatings each comprising at least one antireflection layer, said functional layer being placed between the two antireflection coatings, wherein the antireflection coating placed above the metallic functional layer on the opposite side from the substrate comprises at least two antireflection layers, the antireflection layer furthest from the metallic functional layer being more resistive than the antireflection layer closest to the metallic functional layer.

2. The photovoltaic cell as claimed in claim 1, wherein the antireflection layer furthest from the metallic functional layer has a resistivity of at least 5 times, or even at least 10 times, or even at least 100 times the resistivity of the antireflection layer closest to the metallic functional layer.

3. The photovoltaic cell as claimed in claim 1, wherein the antireflection layer furthest from the metallic functional layer has a resistivity ρ of between 5×10⁻³ Ω.cm and 10 Ω.cm.

4. The photovoltaic cell as claimed in claim 1, wherein the antireflection layer closest to the metallic functional layer has a resistivity ρ of between 10⁻⁵ Ω.cm and 5×10⁻³ Ω.cm, excluding the latter value.

5. The photovoltaic cell as claimed in claim 1, wherein the antireflection layer closest to the metallic functional layer and the antireflection layer furthest from the metallic functional layer comprise the same oxide.

6. The photovoltaic cell as claimed in claim 1, wherein the antireflection layer furthest from the metallic functional layer has an optical thickness representing between 2 and 50% of the optical thickness of the antireflection coating furthest from the substrate.

7. The photovoltaic cell as claimed in claim 1, wherein the antireflection layer furthest from the metallic functional layer has an actual thickness of between 2 and 100 nm.

8. The photovoltaic cell as claimed in claim 1, wherein the antireflection coating placed above the metallic functional layer on the opposite side from the substrate has an optical thickness equal to about one half of the maximum absorption wavelength λₘ of the photovoltaic material.

9. The photovoltaic cell as claimed in claim 1, wherein said antireflection coating placed above the metallic functional layer has an optical thickness of between 0.45 and 0.55 times the maximum absorption wavelength λₘ of the photovoltaic material, these values being inclusive.

10. The photovoltaic cell as claimed in claim 1, wherein the antireflection coating placed beneath the metallic functional layer in the direction of the substrate has an optical thickness equal to about one eighth of the maximum absorption wavelength λₘ of the photovoltaic material.

11. The photovoltaic cell as claimed in claim 1, wherein said anti-reflection coating placed beneath the metallic functional layer has an optical thickness of between 0.075 and 0.175 times the maximum absorption wavelength λₘ of the photovoltaic material or of the product of the absorption spectrum of the photovoltaic material multiplied by the solar spectrum, these values being inclusive.

12. The photovoltaic cell as claimed in claim 1, wherein the electrode coating comprises, directly on said substrate, a base antireflection layer having a low refractive index n₂₂ close to that of the substrate.

13. The photovoltaic cell as claimed in claim 12, wherein said base antireflection layer has a physical thickness of between 50 and 300 nm.

14. The photovoltaic cell as claimed in claim 1, wherein the functional layer is deposited above a wetting layer comprising an oxide.

15. The photovoltaic cell as claimed in claim 1, wherein the functional layer is placed directly on at least one subjacent blocker coating and/or directly beneath at least one superjacent blocker coating.

16. The photovoltaic cell as claimed in claim 1, wherein at least one blocker coating comprises Ni or Ti or an Ni-based alloy.

17. The photovoltaic cell as claimed in claim 1, wherein the coating beneath the metallic functional layer in the direction of the substrate comprises a layer comprising a mixed oxide.

18. The photovoltaic cell as claimed in claim 1, wherein the coating beneath the metallic functional layer in the direction of the substrate and/or the coating above the metallic functional layer comprise/comprises a layer having a refractive index equal to or greater than 2.35.

19. The photovoltaic cell as claimed in claim 1, further comprising a coating comprising a photovoltaic material, above the electrode coating on the opposite side from the substrate.

20. The photovoltaic cell as claimed in claim 1, wherein said electrode coating comprises a stack for architectural glazing.

21. A substrate coated with a thin-film stack for a photovoltaic cell as claimed in claim 1.

22-24. (canceled)

25. The photovoltaic cell of claim 5, wherein the oxide is selected from zinc oxide ZnO, tin oxide SnO₂, titanium oxide TiO₂, gallium oxide Ga₂O₃, indium oxide In₂O₃, silicon oxide SiO₂, a mixed indium tin oxide ITO, a mixed gallium zinc oxide GZO, a mixed indium zinc oxide IZO, a mixed zinc tin oxide Zn₂SnO₄ and a mixed indium gallium zinc oxide IGZO.
